(19) United States
(12) Patent Application Publication
(10) Pub. No.: US 2020/0022280 A1
(43) Pub. Date: Jan. 16, 2020

(54) Composite of Heat Sink and Electrical and/or Electronic Component

(71) Applicant: Siemens Aktiengesellschaft, Muchen, DE (US)

(72) Inventors: Florian Eder, Erlangen (DE); Volker Muhrer, Fürth (DE); Sven Pihale, Stopfenheim (DE)

(73) Assignee: Siemens Aktiengesellschaft, München (DE)

(21) Appl. No.: 16/491,056

(22) PCT Filed: Jan. 24, 2018
(86) PCT No.: PCT/EP2018/051699

§ 371 Date: Sep. 4, 2019

(30) Foreign Application Priority Data
Mar. 6, 2017 (DE) 10 2017 203 583.8

(51) Int. Cl. H05K 7/20; C09K 5/14; B33Y 80/00; F28F 21/04; F28F 21/08

(52) U.S. Cl. CPC H05K 7/2039; C09K 5/14; H02K 9/22; F28F 21/04; F28F 21/081; B33Y 80/00

(57) ABSTRACT

Various embodiments include a composite comprising: a cooling system; a surface to be cooled including at least a part of an electrical and/or electronic component; and a set of chemical bonds joining the cooling system to the surface.

### CROSS-REFERENCE TO RELATED APPLICATIONS

This application is a U.S. National Stage Application of International Application No. PCT/EP2018/051699 filed Jan. 24, 2018, which designates the United States of America, and claims priority to DE Application No. 10 2017 203 583.8 filed Mar. 6, 2017, the contents of which are hereby incorporated by reference in their entirety.

### TECHNICAL FIELD

The present disclosure relates to electric components and circuits. Various embodiments may include electrical and/or electronic components such as circuit breakers and motors with a cooling system.

### BACKGROUND

Electrical and electronic components such as circuit breakers and motors, in spite of many years of optimization work, generate waste heat in the range from 1% to 5% of their power consumption. If this heat is not removed, there is a drop in their efficiency, their lifetime, and/or their reliability.

Cooling systems for removal of heat are currently being mounted onto the regions to be cooled by different modes of assembly, for example as prefabricated heat sinks. For example, heat sinks are adhesive-bonded, in which case the adhesives are favorably still optimized with regard to their thermal conductivity—for example by introducing thermally conductive particles. On the other hand, thermally conductive pastes are utilized for mounting, but there is the risk here that the thermally conductive pastes will have to be exchanged regularly.

The best removal of heat is provided by thermal bonds produced via sintering methods. However, a disadvantage here is that the formation of thermal contacting requires process temperatures around 250° C. or more. These stresses are withstood only by few electrical and/or electronic components, especially since the heat sink to be bonded to the surface to be cooled generally also stores this high temperature over a certain period of time. Nevertheless, ceramic cooling elements are nowadays being installed on circuits for power electronics, since these promise reduced heat transfer resistance in combination with an altered overall system construction. However, these heat sinks mean increased manufacturing expenditure of, for example, a total cost of €30 to 40 per heat sink in electronic circuit breakers.

With rising integration density and component miniaturization, there is likewise an increase in the demands on the removal of heat by the cooling systems. These are fulfilled only inadequately by greater dimensions of the cooling elements and/or an improvement in thermal coupling through reduction in the number of material transitions in the overall system. An additional factor is that the requirement for the removal of heat also depends on the ambient conditions. If, for example, an inverter is being operated in the desert, more complex cooling measures have to be taken than in the case of an identical electrical and/or electronic component in central Europe.

### SUMMARY

The teachings of the present disclosure describe a cooling system capable of being mass-produced for a composite composed of heat sink and electrical and/or electronic component, which, in spite of being mass-produced, is also readily alterable and/or adaptable. For example, some embodiments include a composite composed of a cooling system and a surface to be cooled that is part of an electrical and/or electronic component, wherein the composite is joined together by the formation of chemical, especially covalent, bonds.

In some embodiments, the chemical bonds are van der Waals bonds, ionogenic bombs and/or covalent bonds.

In some embodiments, the chemical bonds are polar bonds constructed via polarizing halogen-, sulfur-, oxygen- and/or nitrogen-containing functional groups.

In some embodiments, the composite is obtainable by means of 3D printing.

In some embodiments, the print bed is the surface of the electrical and/or electronic component and the cooling system is constructed by means of 3D printing.

In some embodiments, the material to be printed for construction of the cooling system comprises at least one reactive group selected from the following groups: halogen/halide such as fluorine, chlorine, bromine, iodine atom; pseudohalogen/pseudohalide such as CN group, SCN group; amino group, amide group, aldehyde group, keto group, carboxyl group, thiol group, hydroxyl group, acryloyloxy group, methacryloyloxy group, epoxy group, isocyanate group, ester group, sulfo group, phosphoric acid group, vinyl group.

In some embodiments, the reactive groups are printed in the form of organometallic compounds. In some embodiments, at least one organometallic compound is present, for example, in the form of a complex-type compound with one or more ligands. In some embodiments, the complex-type compound comprises a central atom selected from the group of the following possible central atoms: silicon, aluminum, zirconium and/or titanium.

In some embodiments, what are called “waterglasses” can be used for construction of the composite. In some embodiments, the composite is constructed using waterglasses comprising, for example, silicon-, zirconium- and/or aluminum-oxygen bonds such as —Si—O—Si—, —Al—O—Al—, —Si—O—Al—, —Zr—O—Zr—, —Si—O—Zr—, —Zr—O—Al—O—Si—, —Si—O—Al—O—Zr—, and any further combinations thereof.

In some embodiments, the printable compounds are in the form of pastes and/or in the form of a dispersion. In some embodiments, the printable compounds are in pure form or in a mixture with a solvent.

In some embodiments, the printable materials comprise thermally conductive particles, for example those that are based on metals and/or ceramics. In some embodiments, the filler is in the form of one or more size fraction(s), material fraction(s) and/or shape fraction(s). In some embodiments, the filler comprises particles in platelet form, rod form and/or bead form. In some embodiments, the filler is present in an amount of 20% to 70% by volume, based on the material to be printed.

### DETAILED DESCRIPTION

Accordingly, the present disclosure describes composites composed of a cooling system and a surface to be cooled that is part of an electrical and/or electronic component, wherein the composite is joined together by the formation of chemical, especially covalent, bonds. In some embodiments, there are chemical bonds in the form of van der Waals bonds, ionogenic bombs and/or covalent bonds in the composite. In some embodiments, the chemical bonds in the composite are in the form of polar bonds constructed via polarizing halogen-, sulfur-, oxygen- and/or nitrogen-containing functional groups.

In some embodiments, the composite is obtainable by means of 3D printing. In some embodiments, the print bed is the surface of the electrical and/or electronic component and the cooling system is constructed by means of 3D printing. In some embodiments, the composite is one composed of a cooling system disposed on a surface to be cooled that is part of an electrical and/or electronic component, wherein the composite is obtainable by means of 3D printing, wherein the print bed is the surface of the electrical and/or electronic component and the cooling system is constructed thereon by means of 3D printing.

In some embodiments, the material to be printed for construction of the cooling system comprises at least one reactive group selected from the following groups: halogen/halide such as fluorine, chlorine, bromine, iodine atom; pseudohalogen/pseudohalide such as CN group, SCN group; amino group, amide group, aldehyde group, keto group, carboxyl group, thiol group, hydroxyl group, acryloyloxy group, methacryloyloxy group, epoxy group, isocyanate group, ester group, sulfo group, phosphoric acid group, vinyl group. These groups are printable, for example, in the form of organometallic compounds, and in turn, for example, in the form of complex-type compounds having one or more ligands comprising one or more of the abovementioned groups. Examples of suitable central atoms of a complex-type organometallic compound are silicon, aluminum, zirconium and/or titanium.

In some embodiments, it is possible to print what are called “waterglasses”, i.e. fundamentally liquid sodium/potassium silicates that solidify via silicization. The term “waterglass” also includes liquid compounds capable of silicization that are constructed exactly like the abovementioned waterglasses. These are compounds comprising, for example, silicon-, zirconium- and/or aluminum-oxygen bonds such as —Si—O—Si—, —Al—O—Al—, —Si—O—Al—, —Zr—O—Zr—, —Si—O—Zr—, —Zr—O—Al—O—Si—, —Si—O—Al—O—Zr—, and any further combinations thereof.

In some embodiments, the material to be printed is in the form, for example, of a paste and/or in the form of a dispersion. In some embodiments, the material to be printed is, for example, in pure form or in a mixture with a solvent. In some embodiments, the printed materials comprise thermally conductive particles, for example those based on metals and/or ceramics. Suitable thermally conductive particles, apart from the known metallic or ceramic particles, for example those based on metal oxides, are also, for example, nitrides as well, such as boron nitride. The fillers may be in one or more fraction(s) comprising particles in platelet form, rod form and/or bead form.

“Filler fraction” in the present disclosure refers, for example, to one type of filler, whether in terms of size, shape of the material and/or construction. The fillers may be coated and uncoated and may take the form of core-shell particles, of solid particles and/or of hollow particles, or of any mixtures thereof.

In some embodiments, the materials are printed in the form of aluminosilicate hybrid materials and/or waterglasses. The use of 1-K (one-component) or 2-K (two-component) systems in printing has been found to be especially advantageous. The printing of 2-K systems by the methods mentioned below is known to the person skilled in the art. The printable materials solidify and/or harden in the course of printing, followed by post-curing that may be in thermal or UV-initiated form.

In the case of printing by means of standard 3D methods such as fused deposition molding (FDM), fused filament fabrication (FFF), multijet fusion, the material then forms a chemical bond either with the print bed or with a lower, already printed layer, more particularly either an ionogenic bond, a van der Waals bond and/or a simple or multiple covalent bond.

In some embodiments, the print bed, i.e. the surface of the electrical and/or electronic component for formation of the chemical bond, is pretreated prior to the printing, for example cleaned, roughened and/or coated with an adhesion promoter layer.

In some embodiments, there is a composite composed of a cooling system and an electrical and/or electronic component, in which heat transfer is optimized by a reduction in material transitions, in such a way that the composite is bonded by the formation of chemical bonds, especially also covalent bonds. For production of the composite, it is possible to use 3D printing methods, wherein the surface to be cooled is usable directly or indirectly as print bed.

What is claimed is:

1. A composite comprising:
a cooling system;
a surface to be cooled including at least a part of an electrical and/or electronic component; and
a set of chemical bonds joining the cooling system to the surface.

2. The composite as claimed in claim 1, wherein the set of chemical bonds includes at least one bond selected from the group consisting of: van der Waals bonds, ionogenic bombs, and covalent bonds.

3. The composite as claimed in claim 1, wherein the set of chemical bonds comprise polar bonds constructed via functional groups comprising at least one polarizing functional group selected from the group consisting of: a halogen-, a sulfur-, an oxygen-, and a nitrogen-containing functional group.

4. The composite as claimed in claim 1, obtained by additive manufacturing.

5. The composite as claimed in claim 4, wherein the surface of the electrical and/or electronic component serves as a print bed and the cooling system is constructed by means of 3D printing.

6. The composite as claimed in claim 4, wherein the cooling system comprises a print material including at least one reactive group for construction selected from the group consisting of: a halogen, a halide, a pseudohalogen, a pseudohalide, an amino group, an amide group, an aldehyde group, a keto group, a carboxyl group, a thiol group, a hydroxyl group, an acryloyloxy group, a methacryloyloxy group, an epoxy group, an isocyanate group, an ester group, a sulfo group, a phosphoric acid group, and a vinyl group.

7. The composite as claimed in claim 6, wherein the reactive groups are printed in the form of organometallic compounds.

8. The composite as claimed in claim 7, wherein at least one organometallic compound is present, for example, in the form of a complex-type compound with one or more ligands.

9. The composite as claimed in claim 8, wherein the complex-type compound comprises a central atom selected from the group consisting of silicon, aluminum, zirconium, and titanium.

10. The composite as claimed in claim 1, further comprising a waterglass.

11. The composite as claimed in claim 10, wherein the waterglass comprises at least one material selected from the group consisting of: silicon-, zirconium-, and aluminum-oxygen bonds.

12. The composite as claimed in claim 1, wherein the printable compounds comprises pastes or a dispersion.

13. The composite as claimed in claim 1, wherein the printable compounds are in pure form or in a mixture with a solvent.

14. The composite as claimed in claim 1, wherein the printable materials comprise thermally conductive particles, for example those that are based on metals and/or ceramics.

15. (canceled)

16. The composite as claimed in claim 14, wherein the filler comprises particles in platelet form, rod form, and/or bead form.

17. The composite as claimed in claim 14, wherein the filler is present in an amount of 20% to 70% by volume, based on the material to be printed.
